(19) United States
(12) Patent Application Publication
(10) Pub. No.: US 2026/0051357 A1
(43) Pub. Date: Feb. 19, 2026

(54) SELECTIVE PLANE DATA PROGRAM VERIFICATION SYSTEM

(71) Applicant: MICRON TECHNOLOGY, INC., BOISE, ID (US)

(72) Inventors: YU-CHUNG LIEN, San Jose, CA (US); ZHENMING ZHOU, San Jose, CA (US)

(21) Appl. No.: 18/808,628

(22) Filed: Aug. 19, 2024

(51) Int. Cl. G11C 29/12

(52) U.S. Cl. CPC G11C 29/1201; G11C 2029/1202

(57) ABSTRACT

A method for programming data in a memory device is described herein. The method includes providing a programming pulse via a controller to each of a plurality of word-lines in each of a plurality of sub-blocks of each of a plurality of planes of the memory device. The method further includes providing a verification pulse via the controller selectively to a set of the word-lines in one or more of the sub-blocks of a proper subset of the planes of the memory device.

### TECHNICAL FIELD

This disclosure relates to writing data to a memory, and particularly to a selective plane data program verification system.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1A illustrates a system for decoding data from a memory sub-system.

FIG. 1B illustrates a simplified block diagram of an example memory device in communication with a memory sub-system controller.

FIG. 2 illustrates an example diagram of a memory device.

FIG. 3 illustrates an example diagram of write voltage patterns.

FIG. 4 illustrates an example diagram of a programming operation on planes of a memory device.

FIG. 5 illustrates another example diagram of write voltage patterns.

FIG. 6 illustrates an example flow diagram of a data programming operation.

FIG. 7 illustrates an example of a computer system in which examples of the present description may operate.

### DETAILED DESCRIPTION

This disclosure relates to writing data to a memory, and particularly to a selective plane data program verification system. A manner of programming data in a memory device and providing program verification is described herein. As described herein, to provide program verification, a verification pulse is selectively provided to a set of word-lines in one or more of the sub-blocks of a proper subset of the planes of the memory device. As described herein, the term “proper subset” refers to a quantity of a set that is less than all of the entire set. Therefore, program verification is described herein as being implemented based on providing a verification pulse to less than all of the planes of a given memory device during program verification. As a result, the memory device can achieve a faster ramping time between programming pulses and verification pulses based on less current workload performed during program verification.

A memory sub-system refers to a storage device, a memory module or some combination thereof. The memory sub-system includes a memory device or multiple memory devices that store data. The memory devices could be volatile or non-volatile memory devices. Some examples of a memory sub-system include high density non-volatile memory devices where retention of data is desired during intervals of time where no power is supplied to the memory device. One example of a non-volatile memory device is a not-AND (NAND) memory device. A non-volatile memory device is a package that includes a die(s). Each such die can include a plane(s). For some types of non-volatile memory devices (e.g., NAND memory devices), each plane includes a set of physical blocks, and each physical block includes a set of pages. Each page includes a set of memory cells, which are commonly referred to as cells. A cell is an electronic circuit that stores information. A cell stores one or more bits of binary information and has various logic states that correlate to the number of bits being stored. The logic states are be represented by binary values, such as ‘0’ and ‘1’, or as combinations of such values, such as ‘00’, ‘01’, ‘10’ and ‘11’.

A memory device includes multiple cells arranged in a two-dimensional or a three-dimensional array. In some examples, memory cells are formed on a silicon wafer in an array of columns connected by conductive lines (also referred to as bitlines, or BLs) and rows connected by conductive lines (also referred to as wordlines or WLs). A wordline is a row of associated memory cells in a memory device that are used with a bitline or multiple bitlines to generate the address of each of the memory cells. The intersection of a bitline and a wordline defines an address of a given memory cell.

A block refers to a unit of the memory device used to store data. In various examples, the unit could be implemented as a group of memory cells, a wordline group, a wordline or as individual memory cells. Multiple blocks are grouped together to form separate partitions (e.g., planes) of the memory device to enable concurrent operations to take place on each plane. A solid-state drive (SSD) is an example of a memory sub-system that includes a non-volatile memory device(s) and a memory sub-system controller to manage the non-volatile memory devices.

When a memory device performs a write operation (e.g., a data programming operation) to write (or program) data to memory, the memory device may apply one or more programming pulses to apply a voltage to memory cells to cause those cells to store a desired data state (e.g., a “0” or a “1”). After applying a programming pulse, the memory device may perform a program verify operation (or “program verification”) to verify that the desired data state is stored by the memory cells. If the desired data state is stored (e.g., by a threshold quantity or percentage of memory cells), then the write operation passes. If the desired data state is not stored (e.g., by a threshold quantity or percentage of memory cells), then the memory device can perform a corrective action, such as by applying one or more additional programming pulses, preventing further use of the memory cells and/or a block that includes the memory cells, or the like.

Performing a program verify operation increases the reliability of the memory device by ensuring that the write operation was successfully performed to program memory cells to a desired state. However, performing a program verify operation requires power and time. Thus, a write operation that includes a program verify operation consumes more power (e.g., results in greater peak current and/or greater average current) and has a longer write time (e.g., a program time) than a write operation that does not include a program verify operation. Thus, a memory device can reduce power consumption and increase performance (e.g., via faster write times) by using a write operation that does not include a program verify operation. However, this leads to reliability risks because the memory device will be unable to determine whether write operations are successful. For example, skipping or refraining from performing a program verify operation may lead to incorrect data being stored by the memory device, especially as the memory device ages and memory cells (and other memory components, such as access lines and bit lines) degrade.

As described herein, a memory device can be organized such that a set of wordlines can be formed as a sub-block, and a group of sub-blocks can be formed as a plane. A “sub-block”, as described herein, is a portion of a memory block. As an example, in the physical structure of a memory device, a plane can be a vertical collection of vertical sub-blocks, across which the horizontal wordlines can extend. Thus, the planes of a memory device can be arranged adjacent to each other in the physical construct of the memory device. Some implementations described herein can implement a program verification by providing a verification pulse on a proper subset of planes (e.g., a single plane) of the memory device during a programming operation. Based on the physical arrangement of the planes of the memory device with respect to each other, providing a verification pulse to a proper subset of the planes can be potentially determinative of a problem with any of the planes of the memory device, including one or more planes to which a verification pulse is not provided. Accordingly, by minimizing the quantity of verification pulses that are provided during program verification, the overall workload associated with the circuitry of the memory device can be reduced. As a result, the ramping time of the verification pulse can be increased to provide a faster programming operation.

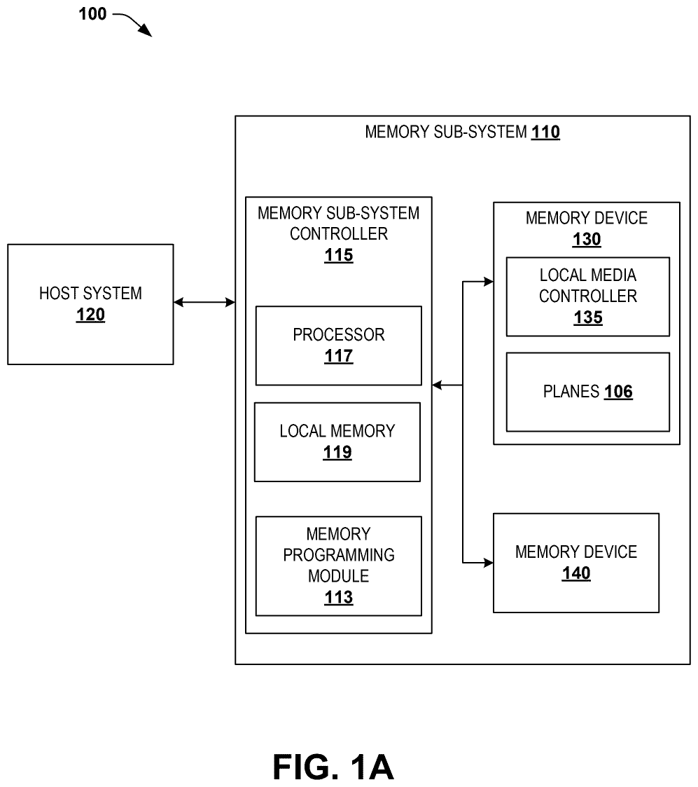

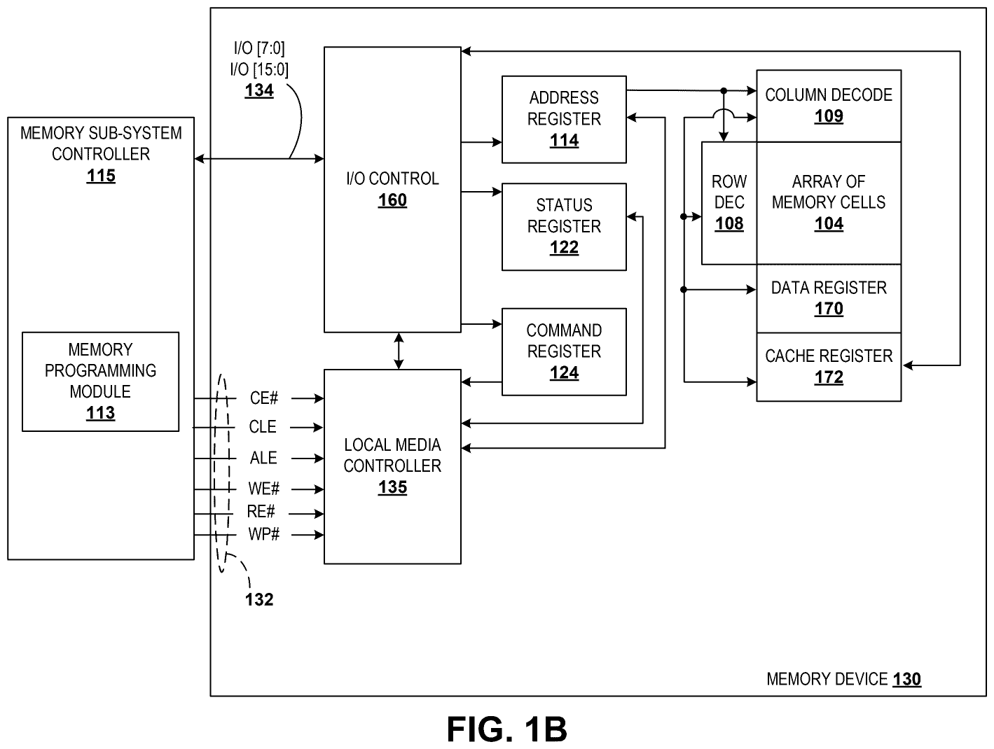

FIG. 1A illustrates a system 100 that includes a memory sub-system 110 that can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card and a hard disk drive (HDD). Examples of memory modules include a dual in-line memory module (DIMM), a small outline DIMM (SO-DIMM) and various types of non-volatile dual in-line memory modules (NVDIMMs).

The system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment or a networked commercial device) or such computing device that includes memory and a processing device. The system 100 can include a host system 120 that is coupled to one or more memory sub-systems 110. In some examples, the host system 120 is coupled to different types of the memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory device(s) 130) when the memory sub-system 110 is coupled with the host system 120 by the physical host interface (e.g., PCIe or CXL bus). The physical host interface can provide an interface for passing control, address, data and other signals between the memory sub-system 110 and the host system 120. FIG. 1A illustrates a memory sub-system 110 as an example. In general, the host system 120 can access multiple memory sub-systems via a same communication connection, multiple separate communication connections and/or a combination of communication connections.

The memory device 130 and the memory device 140 are implemented as non-transitory computer readable media. The memory device 130 and the memory device 140 can include any combination of the different types of non-volatile memory devices and/or volatile memory devices. The volatile memory devices (e.g., the memory device 140) can be, but are not limited to, random access memory (RAM), such as dynamic random access memory (DRAM) and synchronous dynamic random access memory (SDRAM).

Some examples of non-volatile memory devices (e.g., memory device(s) 130) include negative-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory device(s) 130 include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) or higher, can store multiple bits per cell. In some examples, each of the memory device(s) 130 can include one or more arrays of memory cells such as SLCs, MLCs, TLCs, QLCs or some combination thereof. In some examples, a particular memory device can include an SLC portion, an MLC portion, a TLC portion and/or a QLC portion of memory cells. The memory cells of the memory device(s) 130 can be grouped as pages that can refer to a logical unit of the memory device used to store data. In some types of memory (e.g., NAND), pages can be grouped to form blocks. The blocks can include sub-blocks and can be organized across a set of planes 106 of the memory device 130.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, electrically erasable programmable read-only memory (EEPROM), etc.

A memory sub-system controller 115 (or controller 115 for simplicity) communicates with the memory device(s) 130 to perform operations such as reading data, writing data or erasing data at the memory device(s) 130 and other such operations. The memory sub-system controller 115 can include hardware such as one or more integrated circuits and/or discrete components, a buffer memory or some combination thereof. The hardware can include a digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), etc.) or another suitable processor.

The memory sub-system controller 115 can include a processing device, which includes one or more processors (e.g., the processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120. The local memory 119 is a non-transitory computer-readable medium.

In some examples, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another example, a memory sub-system 110 does not include a memory sub-system controller 115 and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device(s) 130. The memory sub-system controller 115 can be responsible for other operations such as wear leveling operations, garbage collection operations, error detection and error-correcting code (ECC) operations, encryption operations, caching operations and address translations between a logical address (e.g., a logical block address (LBA), namespace) and a physical address (e.g., physical block address) that are associated with the memory device(s) 130. The memory sub-system controller 115, for example, may employ a Flash Translation Layer (FTL) to translate logical addresses to corresponding physical memory addresses, which can be stored in one or more FTL mapping tables. In some instances, the FTL mapping table can be referred to as a logical-to-physical (L2P) mapping table storing L2P mapping information. The memory sub-system controller 115 can further include host interface circuitry to communicate with the host system 120 via the physical host interface. The host interface circuitry can convert the commands received from the host system into command instructions to access the memory device(s) 130 as well as convert responses associated with the memory device(s) 130 into information for the host system 120.

The memory sub-system 110 can also include additional circuitry or components that are not illustrated. For example, the memory sub-system 110 can include a cache or buffer (e.g., DRAM) and address circuitry (e.g., a row decoder and a column decoder) that can receive an address from the memory sub-system controller 115 and decode the address to access the memory device(s) 130.

In some examples, the memory device(s) 130 include local media controllers 135 that operate in concert with the memory sub-system controller 115 to execute operations on one or more memory cells of the memory device(s) 130. An external controller (e.g., the memory sub-system controller 115) can externally manage the memory device 130 (e.g., perform media management operations on the memory device 130). In some examples, the memory sub-system 110 is a managed memory device, which is a raw memory device 130 having control logic (e.g., local media controller 135) on the die and a controller (e.g., the memory sub-system controller 115) for media management within the same memory device package. An example of a managed memory device is a managed NAND (MNAND) device.

In operation, the host system 120 manages and controls the flow of data between itself and the memory sub-system 110, ensuring efficient data storage and retrieval operations. More generally, the host system 120 employs the memory sub-system 110 to write data to and read data from the memory sub-system 110. For instance, the host system 120 processes these request for reading and/or write data by interacting with the memory sub-system 110, managing the flow of data to and from the memory device 130 and/or the memory device 140 within the memory sub-system 110. This reading and writing of data enables operation of computing systems where data access and management is needed.

In various examples, the memory sub-system 110 includes a memory programming module 113 that executes programming operations (e.g., data write operations) for programming data in the memory device 130. In some examples, the memory sub-system controller 115 includes at least a portion of the memory programming module 113. In some examples, the memory programming module 113 is part of the host system 120, an application or an operating system. In other examples, local media controller 135 includes a portion of the memory programming module 113 and is configured to perform the functionality described herein.

As described herein, the memory programming module 113 can perform program verification on the data that is programmed in the memory device 130, such as to ensure that the correct data is written to the memory cells of the memory device 130. For example, over time and/or under certain environmental conditions, the memory cells of the memory device 130 can become less reliable with respect to storing data. As a result, data that is programmed into the memory cells of the memory device 130 can become more prone to errors during the programming operation. Thus, program verification can mitigate errors in the data that is written to the memory cells under conditions of less reliability of the memory device 130.

To perform program verification, the memory programming module 113 can provide a verification pulse to sub-blocks of the memory device 130 to which data is written. The verification pulse can be provided subsequent to a programming operation to verify the correctness of the written data. As described herein, the memory programming module 113 can provide the verification pulse to one or more of the sub-blocks of a proper subset of the planes 106 (e.g., one plane 106) of the memory device 130 during a programming operation, as opposed to a memory controller that provides a verification pulse to sub-block(s) of every plane of a memory device. Based on the physical arrangement of the planes 106 of the memory device with respect to each other, providing a verification pulse to a proper subset of the planes 106 can be provide suitable verification of data written to all of the sub-blocks of all of the planes 106 of the memory device 130, including one or more planes 106 to which a verification pulse is not provided. Accordingly, by minimizing the quantity of verification pulses that are provided during program verification, the overall workload associated with the memory device 130 can be reduced. As a result, the memory programming module 113 can increase a ramping time of providing the verification pulse, and thus can provide a faster programming operation.

FIG. 1B illustrates a simplified block diagram of an example of a first apparatus, in the form of a memory device 130, in communication with an example of a second apparatus, in the form of a memory sub-system controller 115 of a memory sub-system (e.g., the memory sub-system 110 of FIG. 1A). Some examples of electronic systems include personal computers, personal digital assistants (PDAs), digital cameras, digital media players, digital recorders, games, appliances, vehicles, wireless devices, mobile telephones, etc. The memory sub-system controller 115 (e.g., a controller external to the memory device 130), can be a memory controller or other external host device.

The memory device 130 includes an array of memory cells 104 logically arranged in rows and columns. As an example, the memory cells 104 can be arranged in an assortment of multiple blocks, with each block including a set of sub-blocks. The blocks/sub-blocks are grouped together to form the planes 106 of the memory device 130. The memory cells 104 form a non-transitory computer-readable medium. Memory cells of a logical row are connected to the same access line (e.g., a wordline) while memory cells of a logical column are selectively connected to the same data line (e.g., a bit line) in some examples. In some examples, a single access line is associated with more than one logical row of memory cells and a single data line may be associated with more than one logical column. Memory cells of at least a portion of the array of memory cells 104 are capable of being programmed to one of at least two target data states.

The memory device 130 includes row decode circuitry 108 and column decode circuitry 109 for decoding address signals. Address signals are received and decoded to access an array of memory cells 104 of the memory device 130. The memory device 130 also includes input/output (I/O) control circuitry 160 to manage input of commands, addresses and data to the memory device 130 as well as output of data and status information from the memory device 130. The memory device 130 has an address register 114 and is in communication with the I/O control circuitry 160, the row decode circuitry 108 and the column decode circuitry 109 to latch the address signals prior to decoding. The memory device 130 also includes a command register 124 in communication with the I/O control circuitry 160 and a local media controller 135 to latch incoming commands.

A controller (e.g., the local media controller 135 internal to the memory device 130) controls access to the array of memory cells 104 in response to the commands and generates status information for the external memory sub-system controller 115. For example, the local media controller 135 is configured to perform access operations (e.g., read operations, programming operations and/or erase operations) on the array of memory cells 104. The local media controller 135 is in communication with the row decode circuitry 108 and the column decode circuitry 109 to control the row decode circuitry 108 and the column decode circuitry 109 in response to the addresses.

As described above in the example of FIG. 1A, the memory programming module 113 can implement programming operations on the memory cells 104 of the memory device 130. The programming operation can include providing one or more programming pulses to the sub-blocks of the memory cells 104 to program the associated data in the memory cells 104. The memory programming module 113 can also provide a verification pulse to one or more of the sub-blocks of one or more of the planes 106.

As an example, the memory programming module 113 can operate in an all plane program mode or a selective plane program mode. In the all plane program mode, the memory programming module 113 provides programming pulses to the sub-blocks of all of the planes 106 of the memory device 130, thereby programming the data in all of the planes 106. Conversely, in the selective plane program mode, the memory programming module 113 can provide programming pulses selectively to one or more of the sub-blocks of one or more of the planes 106. Typically, verification pulses are only provided in the all plane program mode, though program verification can occur in the selective program mode. Additionally, the memory programming module 113 can selectively provide program verification. As an example, the memory programming module 113 can omit program verification, even during a programming operation in the all plane program mode. Additionally, the memory programming module 113 can selectively provide the verification pulses to any combination of the sub-blocks of any combination of the planes 106 during program verification. In this manner, the verification pulses can be provided to any sub-block or sub-blocks in any of the planes 106, as deemed appropriate by the memory programming module 113.

The local media controller 135 is also in communication with a cache register 172. The cache register 172 latches data, either incoming or outgoing, as directed by the local media controller 135 to temporarily store data while the array of memory cells 104 is busy writing or reading, respectively, other data. During a programming operation (e.g., write operation), data is passable from the cache register 172 to the data register 170 for transfer to the array of memory cells 104, and new data can be latched in the cache register 172 from the I/O control circuitry 160. During a read operation, data is passable from the cache register 172 to the I/O control circuitry 160 for output to the memory sub-system controller 115. New data is passable from the data register 170 to the cache register 172. The cache register 172 and/or the data register 170 form (e.g., or form a portion of) a page buffer of the memory device 130. The page buffer includes sensing devices (not shown in FIG. 1B) to sense a data state of a memory cell of the array of memory cells 104. For example, the sensing devices sense a state of a data line connected to that memory cell. The memory device 130 also includes a status register 122 in communication with the I/O control circuitry 160 and the local media controller 135 to latch the status information for output to the memory sub-system controller 115.

The memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE # and/or a write protect signal WP #. Additional or alternative control signals (not shown) can be further received over control link 132 depending upon the nature of the memory device 130. In some examples, the memory device 130 receives command signals (which represent commands), address signals (which represent addresses) and data signals (which represent data) from the memory sub-system controller 115 over a multiplexed input/output (I/O) bus 134 and outputs data to the memory sub-system controller 115 over the I/O bus 134.

In some examples, the commands are received over input/output (I/O) pins [7:0] of the I/O bus 134 at I/O control circuitry 160 and may then be written into the command register 124. The addresses are received over input/output (I/O) pins [7:0] of the I/O bus 134 at I/O control circuitry 160 and written into the address register 114. The data is receivable over input/output (I/O) pins [7:0] for an 8-bit device or input/output (I/O) pins [15:0] for a 16-bit device at I/O control circuitry 160 and is writable into the cache register 172. The data is subsequently written into the data register 170 for programming the array of memory cells 104 in some examples.

In some examples, the cache register 172 is omitted, and in such examples, the data is written directly into the data register 170. Additionally or alternatively, data is output over input/output (I/O) pins [7:0] for an 8-bit device or input/output (I/O) pins [15:0] for a 16-bit device. Moreover, it is noted that although reference is made to I/O pins, in other examples, a different conductive node providing for electrical connection to the memory device 130 by an external device (e.g., the memory sub-system controller 115), such as conductive pads or conductive bumps could be used in addition to or as a replacement for the I/O pins.

The example memory device 130 of FIG. 1B has been simplified. Moreover, in other examples, the functionality of the various block components described with reference to FIG. 1B are not segregated to distinct components or component portions of an integrated circuit device. For example, a single component or component portion of an integrated circuit device could be adapted to perform the functionality of more than one block component of FIG. 1B. Alternatively, components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) are useable in various examples.

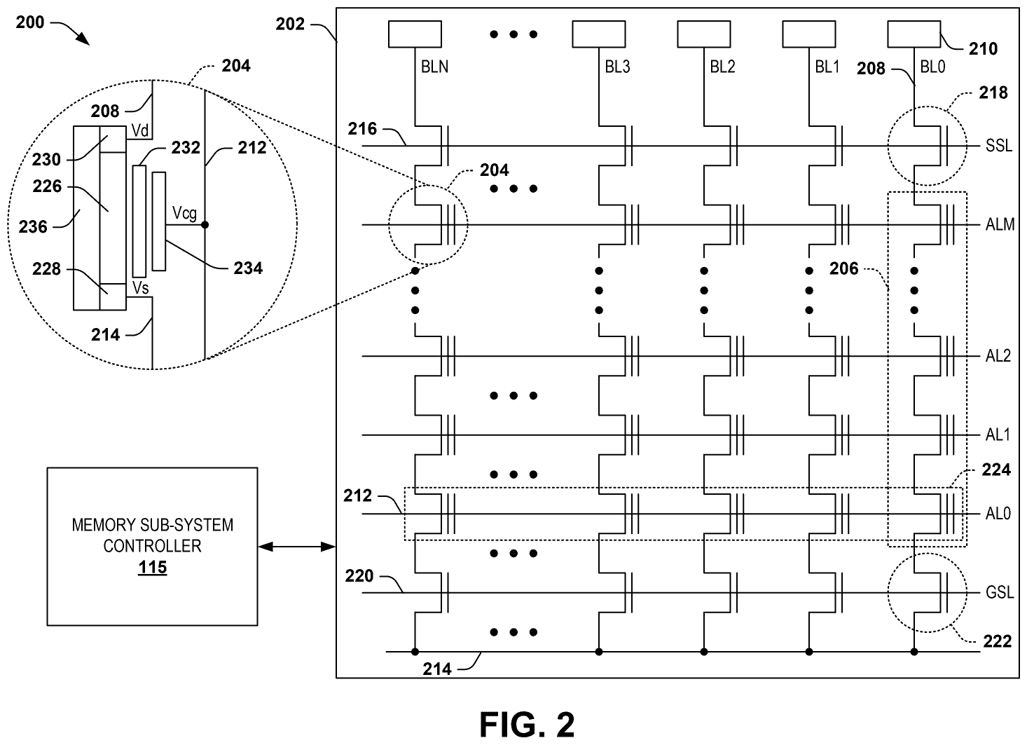

FIG. 2 is an example diagram 200 of a memory device. As described above in connection with FIG. 1, the memory device of the diagram 200 can correspond to the memory device 130 communicatively coupled to the memory sub-system controller 115. As shown in FIG. 2, the memory device 130 may include a memory array 202, which may correspond to a non-volatile memory array 104 described above in connection with FIG. 1B.

In FIG. 2, the memory array 202 is a NAND memory array. However, in some implementations, the memory array 202 may be another type of memory array, such as a NOR memory array, a resistive RAM (RRAM) memory array, a magnetoresistive RAM (MRAM) memory array, a ferroelectric RAM (FeRAM) memory array, a spin transfer torque RAM (STT-RAM) memory array, or the like. In some implementations, the memory array 202 is part of a three-dimensional stack of memory arrays, such as 3D NAND flash memory, 3D NOR flash memory, or the like.

The memory array 202 includes multiple memory cells 204. A memory cell 204 may store an analog value, such as an electrical voltage or an electrical charge, that represents a data state (e.g., a digital value). The analog value and corresponding data state depend on a quantity of electrons trapped or present within a region of the memory cell 204 (e.g., in a charge trap, such as a floating gate), as described below.

A NAND string 206 may include multiple memory cells 204 connected in series. Each NAND string 206 is coupled to a bit line 208 (e.g., a digit line or a column line, demonstrated as BL0-BLN). Data can be read from or written to the memory cells 204 of the NAND string 206 via a corresponding bit line 208 using one or more input/output (I/O) components 210 (e.g., an I/O circuit, an I/O bus, a page buffer, and/or a sensing component, such as a sense amplifier). Memory cells 204 of different NAND strings 206 (e.g., one memory cell 204 per NAND string 206) may be coupled with one another via access lines 212 (e.g., word lines or row lines, demonstrated as AL0-ALM) that select which row (or rows) of memory cells 204 is affected by a memory operation (e.g., a read operation or a write operation).

Each NAND string 206 may be connected to a bit line 208 at one end and a common source line (CSL) 214 at the other end. A string select line (SSL) 216 may be used to control respective string select transistors 218. A string select transistor 218 selectively couples a NAND string 206 to a corresponding bit line 208. A ground select line (GSL) 220 may be used to control respective ground select transistors 222. A ground select transistor 222 selectively couples a NAND string 206 to the common source line 214.

A “page” of memory (or “a memory page”) may refer to a group of memory cells 204 connected to the same access line 212, as shown by reference number 224. In some implementations (e.g., for single-level cells), the memory cells 204 connected to an access line 212 may be associated with a single page of memory. In some implementations (e.g., for multi-level cells), the memory cells 204 connected to an access line 212 may be associated with multiple pages of memory, where each page represents one bit stored in each of the memory cells 204 (e.g., a lower page that represents a first bit stored in each memory cell 204 and an upper page that represents a second bit stored in each memory cell 204). In NAND memory, a page is the smallest physically addressable data unit for a write operation (e.g., a programming operation).

In some implementations, a memory cell 204 is a floating-gate transistor memory cell. In this case, the memory cell 204 may include a channel 226, a source region 228, a drain region 230, a floating gate 232, and a control gate 234. The source region 228, the drain region 230, and the channel 226 may be on a substrate 236 (e.g., a semiconductor substrate). The memory device 130 may store a data state in the memory cell 204 by charging the floating gate 232 to a particular voltage associated with the data state and/or to a voltage that is within a range of voltages associated with the data state. This results in a predefined amount of current flowing through the channel 226 (e.g., from the source region 228 to the drain region 230) when a specified read voltage is applied to the control gate 234 (e.g., by a corresponding access line 212 connected to the control gate 234). Although not shown, a tunnel oxide layer (or tunnel dielectric layer) may be interposed between the floating gate 232 and the channel 226, and a gate oxide layer (e.g., a gate dielectric layer) may be interposed between the floating gate 232 and the control gate 234. As shown, a drain voltage Vd may be supplied from a bit line 208, a control gate voltage Veg may be supplied from an access line 212, and a source voltage Vs may be supplied via the common source line 214 (which, in some implementations, is a ground voltage).

To write or program the memory cell 204, Fowler-Nordheim tunneling may be used. For example, a strong positive voltage potential may be created between the control gate 234 and the channel 226 (e.g., by applying a large positive voltage to the control gate 234 via a corresponding access line 212) while current is flowing through the channel 226 (e.g., from the common source line 214 to the bit line 208, or vice versa). The strong positive voltage at the control gate 234 causes electrons within the channel 226 to tunnel through the tunnel oxide layer and be trapped in the floating gate 232. These negatively charged electrons then act as an electron barrier between the control gate 234 and the channel 226 that increases the threshold voltage of the memory cell 204. The threshold voltage is a voltage required at the control gate 234 to cause current (e.g., a threshold amount of current) to flow through the channel 226. Fowler-Nordheim tunneling is an example technique for storing a charge in the floating gate, and other techniques, such as channel hot electron injection, may be used.

To read the memory cell 204, a read voltage may be applied to the control gate 234 (e.g., via a corresponding access line 212), and an I/O component 210 (e.g., a sense amplifier) may determine the data state of the memory cell 204 based on whether current passes through the memory cell 204 (e.g., the channel 226) due to the applied voltage. A pass voltage may be applied to all memory cells 204 (other than the memory cell 204 being read) in the same NAND string 206 as the memory cell 204 being read. For example, the pass voltage may be applied on each access line 212 other than the access line 212 of the memory cell 204 being read (e.g., where the read voltage is applied). The pass voltage is higher than the highest read voltage associated with any memory cell data states so that all of the other memory cells 204 in the NAND string 206 conduct, and the I/O component 210 can detect a data state of the memory cell 204 being read by sensing current (or lack thereof) on a corresponding bit line 208. For example, in a single-level cell (SLC) that stores one of two data states, the data state is a “1” if current is detected, and the data state is a “0” if current is not detected. In a multilevel cell (MLC) that stores one of three or more data states, multiple read voltages are applied, over time, to the control gate 234 to distinguish between the three or more data states and determine a data state of the memory cell 204.

To erase the memory cell 204, a strong negative voltage potential may be created between the control gate 234 and the channel 226 (e.g., by applying a large negative voltage to the control gate 234 via a corresponding access line 212). The strong negative voltage at the control gate 234 causes trapped electrons in the floating gate 232 to tunnel back across the oxide layer from the floating gate 232 to the channel 226 and to flow between the common source line 214 and the bit line 208. This removes the electron barrier between the control gate 234 and the channel 226 and decreases the threshold voltage of the memory cell 204 (e.g., to an empty or erased state, which may represent a “1”).

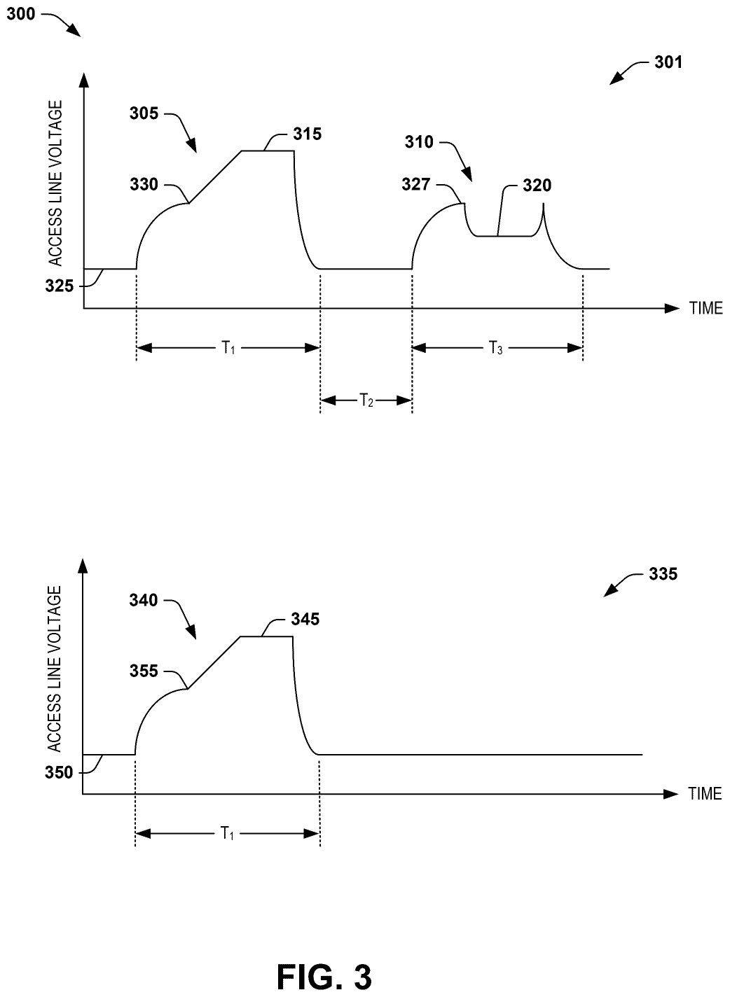

FIG. 3 illustrates an example diagram 300 of write voltage patterns. FIG. 3 shows an example one-pulse, one-verify (1P1V) write voltage pattern and an example one-pulse, zero-verify (1P0V) write voltage pattern. The 1P1V write voltage pattern and the 1P0V write voltage pattern may be applied to a single sub-block of memory to program the memory cells included in that sub-block. For example, a sub-block may include a subset of NAND strings and/or memory cells included in a block, and each sub-block may be mutually exclusive from every other sub-block (e.g., may not include any of the same NAND strings and/or memory cells). A bit line may be shared by multiple sub-blocks.

As shown in FIG. 3, and by reference number 301, a 1P1V write voltage pattern includes a single programming pulse 305 that is followed by a verification pulse 310 corresponding to a program verification operation. The programming pulse 305 is associated with a program voltage 315, and the verification pulse 310 is associated with a verify voltage 320. In the example of FIG. 3, the verify voltage 320 is demonstrated at an amplitude for a selected wordline.

As further shown in FIG. 3, when the memory sub-system controller 115 performs a 1P1V write operation using a 1P1V write voltage pattern, the memory sub-system controller 115 raises the voltage on a selected access line from a baseline voltage 325 to the program voltage 315 during a first time period T₁ that corresponds to the programming pulse 305. The program voltage 315 programs memory cells on the selected access line to a desired state. In some cases, applying the program voltage 315 to the selected access line programs a first set of memory cells (e.g., pass memory cells) on the selected access line to the desired state and fails to program a second set of memory cells (e.g., fail memory cells) on the selected access line to the desired state. After applying the program voltage 315, the memory sub-system controller 115 may reduce the voltage on the selected access line to the baseline voltage 325.

After a second time period T₂ subsequent to the reduction of the program voltage 315, the memory sub-system controller 115 may then raise the voltage on the selected access line from the baseline voltage 325 up to a ramp amplitude, demonstrated at 327, and down to the amplitude of the verify voltage 320 (for a selected wordline) during a third time period T₃ that corresponds to the verification pulse 310. At the amplitude of the verify voltage 320, the memory sub-system controller 115 may perform a sensing operation (e.g., a read operation) to detect whether the verify voltage 320 applied to a memory cell causes that memory cell to conduct (e.g., whether current flows through the memory cell when the verify voltage 320 is applied). Based on a desired state of the memory cell and based on whether the memory cell conducts when the verify voltage 320 is applied, the memory sub-system controller 115 may identify the memory cell as a pass memory cell that stores the desired state or a fail memory cell that does not store the desired state. For example, in a single-level memory cell that stores one of two data states, the memory sub-system controller 115 may apply a verify voltage 320 that is between a first threshold voltage corresponding to a first data state (e.g., 1) and a second threshold voltage corresponding to a second data state (e.g., 0). In this example, the memory cell stores the first data state (e.g., 1) if current is detected, and the memory cell stores the second data state (e.g., 0) if current is not detected.

After applying the verify voltage 320, the memory sub-system controller 115 may reduce the voltage on the selected access line to the baseline voltage 325 to complete the 1P1V write operation. In some implementations, the verification pulse 310 is performed to determine whether a threshold quantity of memory cells (e.g., a threshold number or a threshold percentage) have been successfully programmed. The write operation may pass or fail based on whether the threshold quantity of memory cells have been successfully programmed.

In some implementations, the memory sub-system controller 115 may first raise the voltage on the selected access line from the baseline voltage 325 to a pass voltage 330 that is between the baseline voltage 325 and the program voltage 315. When the memory sub-system controller 115 determines that the pass voltage 330 has been reached, the memory sub-system controller 115 may then raise the voltage on the selected access line from the pass voltage 330 to the program voltage 315. In some implementations, the memory sub-system controller 115 may apply the pass voltage 330 to the selected access line to reduce the likelihood of overprogramming memory cells on the selected access line to a data state other than the desired data state (e.g., a data state associated with a higher threshold voltage than the desired data state). Additionally, or alternatively, the memory sub-system controller 115 may apply the pass voltage 330 to all access lines (e.g., in a block, sub-block, or page of memory to be programmed), including both selected access lines (e.g., connected to memory cells that are to be programmed) and unselected access lines (e.g., connected to memory cells that are not to be programmed), as part of the programming operation. For example, the memory sub-system controller 115 may apply the pass voltage 330 to unselected access lines to reduce program disturbs (e.g., inadvertent programming of memory cells on unselected access lines). In some implementations, the memory sub-system controller 115 may apply a different pass voltage 330 to selected access lines as compared to unselected access lines.

As further shown in FIG. 3, and by reference number 335, a 1P0V write voltage pattern includes a single programming pulse 340 that is not followed by a program verify operation. The programming pulse 340 is associated with a program voltage 345.

As further shown in FIG. 3, when the memory sub-system controller 115 performs a 1P0V write operation using a 1P0V write voltage pattern, the memory sub-system controller 115 raises the voltage on a selected access line from a baseline voltage 350 to a program voltage 345 during a first time period T₁ that corresponds to the programming pulse 340, in a similar manner as described above in connection with the 1P1V write operation. However, unlike the 1P1V write operation, the memory sub-system controller 115 does not perform a program verify operation after applying the single programming pulse 340 in the 1P0V write operation.

Because the 1P0V write operation includes fewer program verify operations than the 1P1V write operation, the 1P0V write operation has a faster write time than the 1P1V write operation and consumes less power than the 1P1V write operation. However, because the 1P0V write operation does not include a program verify operation, the 1P0V write operation may be less reliable than the 1P1V write operation. As described herein, a data programming operation can include the use of both 1P1V and 1P0V write operations to provide for a combination of speed and reliability, thereby reducing power consumption and reducing write times while still maintaining reliable operation.

The data programming operation described in the example of FIG. 3 is based on a single select gate drain (1SGD) data programming operation or. However, the data programming principles and the program verification principles described herein can be equally applicable to a double select gate drain (2SGD) operation. In the 2SGD write operation, the voltage patterns can be provided the same as the 1SGD voltage pattern demonstrated in the example of FIG. 3, but that instead includes two consecutive programming pulses 305. Therefore, for a 2SGD+1P1V data write operation, the voltage patterns would include a first programming pulse 305, followed by a second programming pulse 305 (that could be approximately identical to the first programming pulse 305), followed by the verification pulse 310. Similarly, for a 2SGD+1P0V data write operation, the voltage patterns would include a first programming pulse 305, followed by a second programming pulse 305 (that could be approximately identical to the first programming pulse 305), with no subsequent verification pulse 310. The program verification operation described herein can thus be applicable to either of 1SGD or 2SGD data write operations. Furthermore, the write operation and the program verification operation described herein can also be applicable to a ganged programming pulse having a long enough duration to program two sub-blocks, similar to a 2SGD data write operation.

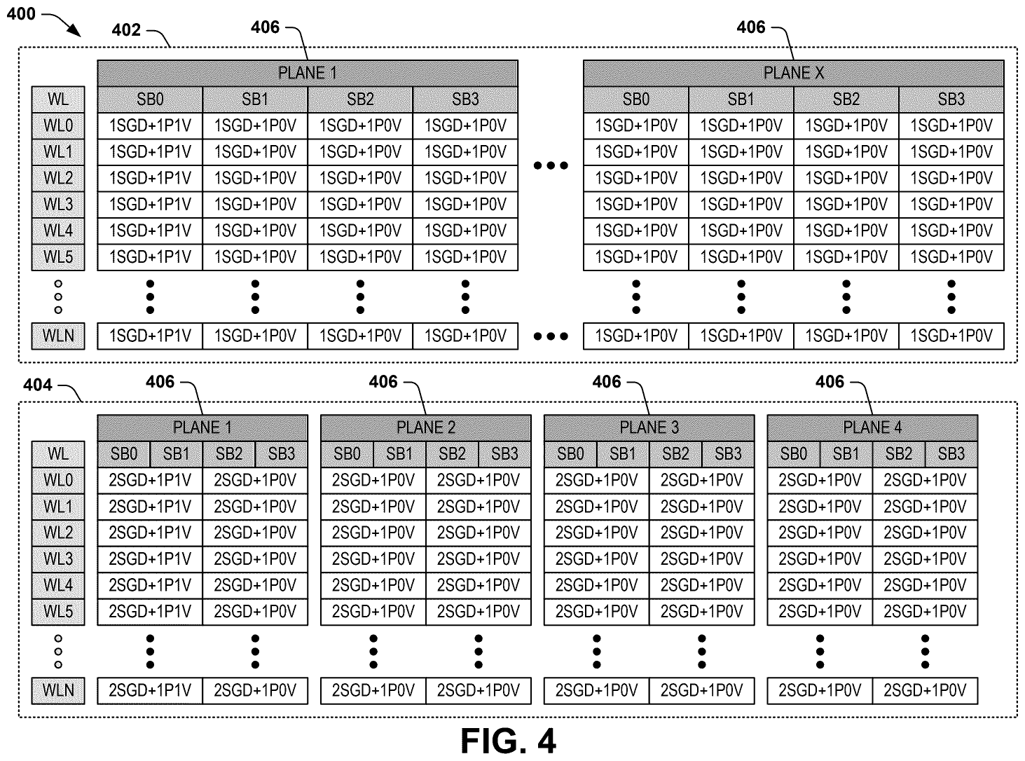

FIG. 4 illustrates an example diagram 400 of a data programming operation on planes of a memory device (e.g., the memory device 130). The diagram 400 includes a first portion 402 and a second portion 404. The data programming operation described in the example of FIG. 4 can correspond to large set of the data write operations described in the example of FIG. 3.

The first portion 402 includes a set of X planes 406 of the memory device 130, where X is an integer greater than one. As one example, the quantity of X can be four. Each of the planes 406 includes a set of four sub-blocks labeled SB0 through SB3. While the example of FIG. 4 demonstrates four sub-blocks for each plane 406, each plane 406 can include more or fewer sub-blocks. The planes 406 are also organized to include a set of wordlines WL, demonstrated as numbering from WL0 to WLN, where N is an integer greater than one. At the intersection of each wordline WL and each sub-block SB is a memory cell that is programmed in the data programming operation of the example of FIG. 4.

The first portion 402 demonstrates 1SGD write operations, and thus a write operation for each single memory cell in each of the sub-blocks SB on each wordline WL. As described herein, the memory programming module 113 in the memory sub-system controller 115 can be configured to implement data verification during a data programming operation. However, as described herein, the memory programming module 113 can provide data verification on a proper subset of the planes 406 of the memory device 130. In the example of FIG. 4, the proper subset of planes 406 is one, demonstrated as the first plane (“PLANE 1”) 406.

Therefore, as demonstrated in the first portion 402, each of the memory cells in the first sub-block SB0 of the first plane 406 are demonstrated as being provided a 1SGD+1P1V data write operation, such as demonstrated above in the example of FIG. 3. Accordingly, each of the memory cells in the first sub-block SB0 of the first plane 406 receives a programming pulse followed by a verification pulse (e.g., as demonstrated at 301 in the example of FIG. 3). The remaining memory cells in each of the other sub-blocks SB1 through SB3 in the first plane 406, and all of the memory cells in all of the sub-blocks SB0 through SB3 in the remaining X−1 planes 406 are provided a 1SGD+1P0V data write operation. Accordingly, each of the remaining memory cells in each of the other sub-blocks SB1 through SB3 in the first plane 406, and all of the memory cells in all of the sub-blocks SB0 through SB3 in the remaining X−1 planes 406, receives a programming pulse followed by no verification pulse (e.g., as demonstrated at 335 in the example of FIG. 3).

The second portion 404 demonstrates 2SGD write operations, and thus a write operation for a group of two memory cells across a pair of adjacent sub-blocks SB on each wordline WL. Similar to as described above, the memory programming module 113 can provide data verification on a proper subset of the planes 406 of the memory device 130. In the second portion 404, similar to the first portion 402, the proper subset of planes 406 is one, demonstrated as the first plane (“PLANE 1”) 406.

Therefore, as demonstrated in the second portion 404, the pair of memory cells in the first and second sub-blocks SB0 and SB1 of the first plane 406 are demonstrated as being provided a 2SGD+1P1V data write operation. Accordingly, the pair of memory cells in the first and second sub-blocks SB0 and SB1 of the first plane 406 are provided a pair of programming pulses followed by a single verification pulse. The remaining pairs of memory cells in each of the associated pairs of sub-blocks SB2 and SB3 in the first plane 406, and all of the memory cells in all of the sub-blocks SB0 through SB3 in the remaining X−1 planes 406 are provided a 2SGD+1P0V data write operation. Accordingly, each of the remaining pairs of memory cells in each of the associated pairs of sub-blocks SB2 and SB3 in the first plane 406, and all of the memory cells in all of the sub-blocks SB0 through SB3 in the remaining X−1 planes 406, receives a pair of programming pulses followed by no verification pulse.

The data programming operation demonstrated in the example of FIG. 4 is by example, and other examples are possible. As described above, the memory programming module 113 can selectively provide verification pulses and is thus not limited to providing verification pulses to every wordline of a sub-block, or two just one sub-block of a plane 406, or to just one plane 406. For example, the memory programming module 113 can provide verification pulses to every other wordline instead of every wordline, or some variation of groups of wordlines. As another example, the memory programming module 113 can provide the verification pulses to sub-blocks other than the first sub-block SB0 or first pair of sub-blocks SB0 and SB1 of a given plane 406. As yet another example, the memory programming module 113 is not limited to providing the verification pulses to the first plane (“PLANE 1”) 406 and is not limited to providing verification pulses to a single plane 406. Instead, the memory programming module 113 can provide verification pulses to any of the other planes 406 as a proper subset of all of the planes 406. By providing verification pulses to a proper subset of the planes 406 as described herein, as opposed to all of the planes 406, the memory programming module 113 can implement data programming operations more rapidly without sacrificing reliability.

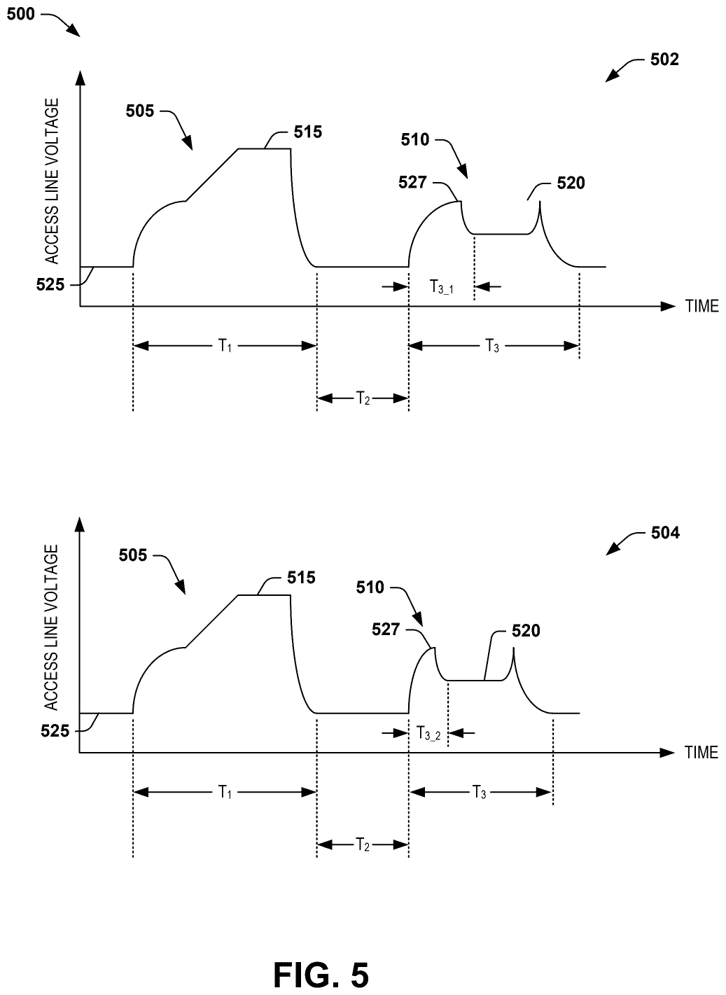

FIG. 5 illustrates another example diagram 500 of write voltage patterns. FIG. 5 demonstrates a first example of a 1SGD+1P1V write voltage pattern at 502 and demonstrates a second example of an example of a 1SGD+1P1V write voltage pattern at 504. The 1SGD+1P1V write voltage patterns 502 and 504 may be applied to a single sub-block of memory to program the memory cells included in that sub-block. For example, a sub-block may include a subset of NAND strings and/or memory cells included in a block, and each sub-block may be mutually exclusive from every other sub-block (e.g., may not include any of the same NAND strings and/or memory cells). A bit line may be shared by multiple sub-blocks.

In each of the write voltage patterns 502 and 504, the 1SGD+1P1V write voltage pattern includes a single programming pulse 505 that is followed by a verification pulse 510 corresponding to a program verification operation. The programming pulse 505 is associated with a program voltage 515, and the verification pulse 510 is associated with a verify voltage 520. The first 1SGD+1P1V write voltage pattern can correspond to the write voltage pattern 301 in the example of FIG. 3. Therefore, in the first 1SGD+1P1V write voltage pattern 502, the memory sub-system controller 115 raises the voltage on a selected access line from a baseline voltage 525 to the program voltage 515 during a first time period T₁ that corresponds to the programming pulse 505 to program memory cells on the selected access line to a desired state. After a second time period T₂ subsequent to the reduction of the program voltage 515, the memory sub-system controller 115 may then raise the voltage on the selected access line from the baseline voltage 525 up to a ramp amplitude, demonstrated at 527, and down to the amplitude of the verify voltage 520 (for a selected wordline) during a third time period T₃ that corresponds to the verification pulse 510. In the first write voltage pattern 502, the ramping time of the voltage amplitude of the verification pulse 510, from the baseline voltage 525 to the ramp amplitude 527, is demonstrated as time period T_{3_1} corresponding to a portion of the time period T₃.

As described herein, the memory sub-system controller 115 can provide verification pulses to a proper subset of the planes of the memory device 130. By providing verification pulses to a proper subset of the planes of the memory device 130, as opposed to all of the planes of the memory device 130, the memory sub-system controller 115 can implement data programming operations more rapidly without sacrificing reliability.

As an example, the first 1SGD+1P1V write voltage pattern 502 can correspond to a typical 1SGD+1P1V data programming operation, such as implemented on all of the planes of the memory device 130. As another example, the second 1SGD+1P1V write voltage pattern 502 can correspond to a 1SGD+1P1V data programming operation that is implemented on a proper subset (e.g., one) of the planes of the memory device 130. In the second 1SGD+1P1V write voltage pattern 504, the memory sub-system controller 115 raises the voltage on a selected access line from a baseline voltage 525 to the program voltage 515 during the first time period T₁ that corresponds to the programming pulse 505 to program memory cells on the selected access line to a desired state. After the time period T₂, the memory sub-system controller 115 may then raise the voltage on the selected access line from the baseline voltage 525 up to the ramp amplitude 527, and down to the amplitude of the verify voltage 520 (for a selected wordline) during a third time period T₃ that corresponds to the verification pulse 510. In the second write voltage pattern 504, the ramping time of the voltage amplitude of the verification pulse 510, from the baseline voltage 525 to the ramp amplitude 527, is demonstrated as time period T_{3_2} corresponding to a portion of the time period T₃. In the example of FIG. 5, the time period T_{3_2} is shorter than the time period T_{3_1}.

Because the memory sub-system controller 115 performs program verification on a proper subset of the planes of the memory device 130, the program verification uses less circuit workload by conserving the current-generating resources of the memory device 130. In other words, by minimizing the quantity of verification pulses that are provided during program verification, the overall workload associated with the circuitry of the memory device 130 can be reduced. As a result, the ramping time of verification pulses, such as the verification pulse 510 in the example of FIG. 5, can be increased to provide a faster programming operation. This is demonstrated in the example of FIG. 5 by the time period T_{3_2} being shorter than the time period T_{3_1}, thus providing for a shorter overall write voltage pattern 504 (T₁+T₂+T₃) relative to the write voltage pattern 502. By increasing the ramping time, and thus decreasing the overall time of the 1SGD+1P1V write voltage pattern, the memory sub-system controller 115 can greatly reduce the amount of time of performing a data programming operation that includes program verification.

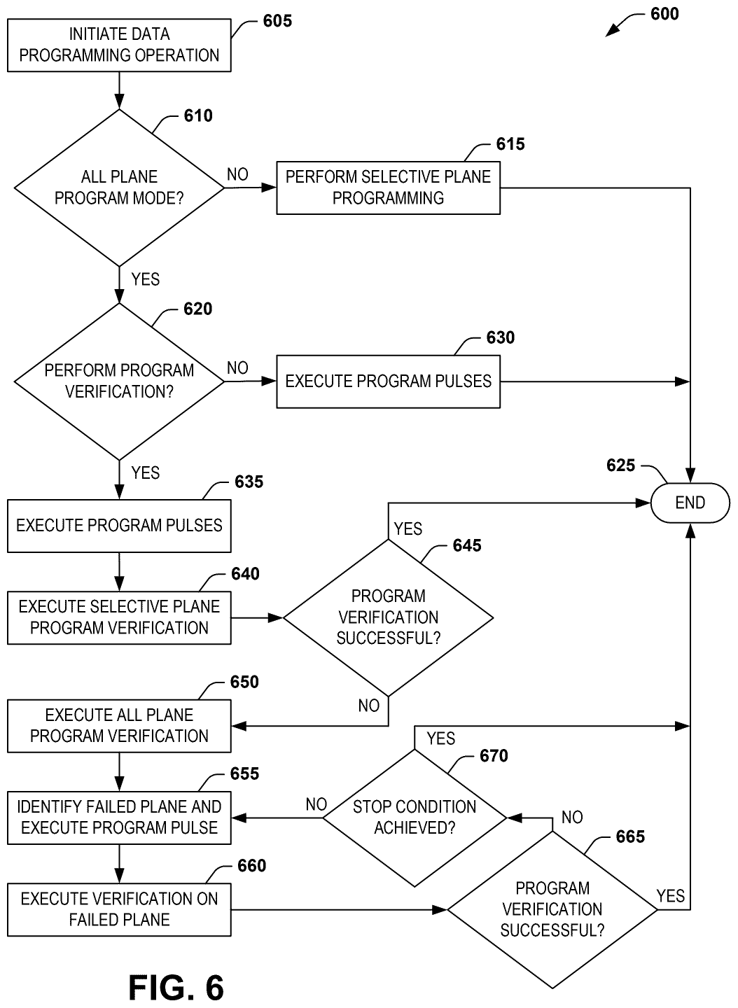

FIG. 6 illustrates a flowchart of an example method 600 for programming data in a memory device (e.g., the memory device 130). The method 600 can be implemented, for example, by a controller, such as the memory sub-system controller 115 (e.g., the memory programming module 113) of the system 100 of FIG. 1A. The method 600 can thus correspond to the data programming operations described herein. The method begins at block 605, in which the controller initiates a data programming operation. Thus, the controller selects a mode for writing data to the memory device 130. The method then proceeds to block 610.

At block 610, a determination is made as to whether the memory device 130 is in an all plane program mode. In the all plane program mode, the controller implements the data programming operation on all of the planes of the memory device 130. Therefore, the controller can be selective as to whether to implement program verification based on whether the memory device 130 is in the all plane program mode. If the determination at block 610 is negative (e.g., NO), the method 600 proceeds to block 615. If the determination at block 610 is positive (e.g., YES), then the method 600 proceeds to block 620.

At block 615, having determined that the memory device 130 is not in the all plane program mode, the controller performs selective plane programming on the memory device 130. Therefore, the controller can provide programming pulses to any combination of wordlines, sub-blocks, and planes of the memory device 130. In the example of FIG. 6, the controller performs the selective plane programming on the memory device 130 without implementing program verification. Therefore, after performing the selective plane programming on the memory device 130, the method 600 proceeds to end block 625 to conclude the data programming operation.

At block 620 (reached if the memory device is in the all plane program mode), a decision is made as to whether the controller is to implement program verification. If the determination at block 620 is negative (e.g., NO), the method 600 proceeds to block 630. If the determination at block 620 is positive (e.g., YES), then the method 600 proceeds to block 635. At block 630, having determined that program verification is not to be performed, the controller executes program pulses to all of the planes of the memory device 130. Because the controller is not performing program verification, the controller provides the program pulses as 1P0V pulses, such as demonstrated at 335 in the example of FIG. 3. After performing the data programming operation on all of the planes on the memory device 130, the method 600 proceeds to end block 625 to conclude the data programming operation.

At block 635 (reached if it is determined that program verification is to be performed), the controller executes program pulses to all of the planes of the memory device 130 and proceeds to block 640. At block 640, the controller executes selective plane program verification. Thus, the controller provides verification pulses to one or more of the sub-blocks of one or more planes as a proper subset of all planes of the memory device 130, as described herein. Therefore, the ramping time of the data programming operation can be increased to provide for a more rapid data programming operation. The method 600 then proceeds to block 645.

At block 645, the controller determines if the program verification is successful. If the determination at block 645 is positive (e.g., YES), the method 600 proceeds to the end block 625 to conclude the data programming operation. If the determination at block 645 is negative (e.g., NO), then the method 600 proceeds to block 650. At block 650, and thus a determination of failure of the program verification, the controller performs an all plane program verification. Therefore, the controller provides a verification pulse to the wordlines of one or more of the sub-blocks of all of the planes of the memory device 130. The method 600 then proceeds to block 655.

At block 655, the controller identifies one or more of the planes that failed program verification and executes another programming pulse on the sub-blocks of the plane(s) that failed program verification. The method 600 then proceeds to block 660, at which the controller executes another program verification on the plane(s) that failed program verification subsequent to the additional programming pulses. The method 600 then proceeds to block 665. At block 665, the controller determines if the subsequent program verification is successful. If the determination at block 665 is positive (e.g., YES), the method 600 proceeds to the end block 625 to conclude the data programming operation. If the determination at block 665 is negative (e.g., NO), then the method 600 proceeds to block 670.

At block 670, the controller checks to determine if a stop condition has been achieved. The stop condition can correspond to any of a variety of watchdog conditions, such as an iteration count of the sequence of SGD+1P1V data write operations achieving a threshold, a timer achieving a timeout, a determination of failure of the memory device, or any of a variety of other stop conditions. If the determination at block 670 is positive (e.g., YES), the method 600 proceeds to the end block 625 to conclude the data programming operation, having determined that the controller is unable to verify the programmed data. If the determination at block 670 is negative (e.g., NO), then the method 600 proceeds back to block 655. The method 600 can thus iteratively continue to provide programming pulses and verification pulses to the plane(s) that failed program verification until achieving successful verification or achieving the stop condition.

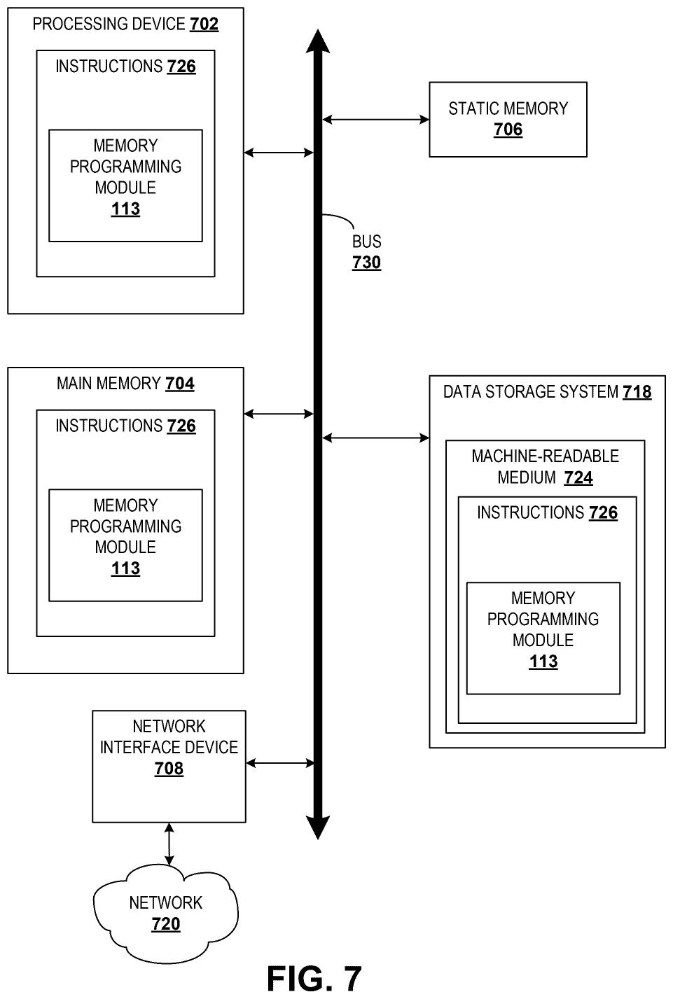

FIG. 7 illustrates an example machine of a computer system 700 (a machine) within which a set of instructions, for causing the machine to perform any one or more of the methodologies discussed herein, can be executed. In some examples, the computer system 700 corresponds to a host system (e.g., the host system 120 of FIG. 1A) that includes, is coupled to, or utilizes a memory sub-system (e.g., the memory sub-system 110 of FIG. 1A) or is used to perform the operations of a controller (e.g., to execute an operating system to perform operations corresponding to the memory programming module 113 of FIG. 1A). In other examples, the machine is connected (e.g., networked) to other machines in a LAN, an intranet, an extranet and/or the Internet. In various examples, the machine operates in the capacity of a server or a client machine in client-server network environment, as a peer machine in a peer-to-peer (or distributed) network environment or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge or any machine capable of executing a set of instructions (sequential or otherwise) that specify actions to be taken by that machine. In other examples, the machine may be a computer within an automotive application, a data center, a smart factory, or other industrial application. Further, while a single machine is illustrated, the term “machine” shall also be taken to include any collection of machines that individually or jointly execute a set (or multiple sets) of instructions to perform the methodologies discussed herein.

The example computer system 700 includes a processing device 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM) or other non-transitory computer-readable media) and a data storage system 718, which communicate with each other via a bus 730.

The processing device 702 represents one or more general-purpose processing devices such as a microprocessor, a central processing unit, etc. More particularly, the processing device 702 can be a complex instruction set computing (CISC) microprocessor, reduced instruction set computing (RISC) microprocessor, very long instruction word (VLIW) microprocessor or a processor implementing other instruction sets or processors implementing a combination of instruction sets. In some examples, the processing device 702 is implemented with a special-purpose processing devices such as an application specific integrated circuit (ASIC), a field programmable gate array (FPGA), a digital signal processor (DSP), network processor, etc. The processing device 702 is configured to execute instructions 726 for performing the operations discussed herein. In some examples, the computer system 700 includes a network interface device 708 to communicate over the network 720.

The data storage system 718 includes a machine-readable storage medium 724 (also known as a computer-readable medium) that store sets of instructions 726 or software for executing the methodologies and/or functions described herein. The machine-readable storage medium 724 is a non-transitory medium. The instructions 726 can also reside, completely or at least partially, within the main memory 704 and/or within the processing device 702 during execution thereof by the computer system 700, the main memory 704 and the processing device 702 also constituting machine-readable storage media. The machine-readable storage medium 724, data storage system 718 and/or main memory 704 can correspond to the memory sub-system 110 of FIG. 1A. Accordingly, the machine-readable storage medium 724, the data storage system 718 and/or the main memory 704 are examples of non-transitory computer-readable media.

In some examples, the instructions 726 include instructions to implement functionality corresponding to the memory programming module 113 of FIG. 1A. As an example, the instructions can include implementing a data programming operation that includes providing a programming pulse to all sub-blocks of all planes of an associated memory device followed by a verification pulse to a proper subset of the planes of the associated memory device. While the machine-readable storage medium 724 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared and otherwise manipulated. It has proven convenient at times, principally for reasons of common usage, to refer to these signals as bits, values, elements, symbols, characters, terms, numbers, etc.

It is noted, however, that all of these and similar terms are to be associated with the appropriate physical quantities and are merely convenient labels applied to these quantities. This description can refer to the action and processes of a computer system or similar electronic computing device that manipulates and transforms data represented as physical (electronic) quantities within the computer system's registers and memories into other data similarly represented as physical quantities within the computer system memories or registers or other such information storage systems.

This description also relates to an apparatus for performing the operations herein. This apparatus can be specially constructed for the intended purposes or this apparatus can include a general purpose computer selectively activated or reconfigured by a computer program stored in the computer. Such a computer program can be stored in a computer readable storage medium, such as, but not limited to, any type of disk including floppy disks, optical disks, CD-ROMs, magnetic-optical disks, read-only memories (ROMs), random access memories (RAMs), EPROMs, EEPROMs, magnetic or optical cards or any type of media suitable for storing electronic instructions, each coupled to a computer system bus.

The algorithms and displays presented herein are not inherently related to any particular computer or other apparatus. Various general purpose systems can be used with programs in accordance with the descriptions herein, or it can prove convenient to construct a more specialized apparatus to perform the method. In addition, the present disclosure is not described with reference to any particular programming language. It will be appreciated that a variety of programming languages can be used to implement the teachings of the disclosure as described herein.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications and variations that fall within the scope of this application, including the appended claims. As used herein, the term “includes” means includes but not limited to, the term “including” means including but not limited to. The term “based on” means “based at least in part on”. Additionally, where the disclosure or claims recite “a,” “an,” “a first” or “another” element, or the equivalent thereof, it should be interpreted to include one or more than one such element, neither requiring nor excluding two or more such elements.

What is claimed is:

1. A method for programming data in a memory device, the method comprising:
providing a programming pulse via a controller to each of a plurality of word-lines in each of a plurality of sub-blocks of each of a plurality of planes of the memory device; and
providing a verification pulse via the controller selectively to a set of the word-lines in one or more of the sub-blocks of a proper subset of the planes of the memory device.

2. The method of claim 1, wherein providing the programming pulse comprises providing a single programming pulse to each of the sub-blocks of each of the planes of the memory device, and wherein providing the verification pulse comprises providing the verification pulse to the set of the word-lines in one of the sub-blocks of the proper subset of the planes of the memory device.

3. The method of claim 1, wherein providing the programming pulse comprises providing two programming pulses to two respective sub-blocks of each of the planes of the memory device, and wherein providing the verification pulse comprises providing the verification pulse to the set of the word-lines in two of the sub-blocks of the proper subset of the planes of the memory device.

4. The method of claim 1, wherein providing the programming pulse comprises providing a ganged programming pulse to two sub-blocks of each of the planes of the memory device, and wherein providing the verification pulse comprises providing the verification pulse to the set of the word-lines in two of the sub-blocks of the proper subset of the planes of the memory device.

5. The method of claim 1, wherein providing the verification pulse comprises providing the verification pulse to each of the word-lines in the one or more of the sub-blocks of the proper subset of the planes of the memory device.

6. The method of claim 1, wherein providing the verification pulse comprises providing the verification pulse to each of the word-lines in the one or more of the sub-blocks of one of the planes of the memory device.

7. The method of claim 1, further comprising:
determining via the controller if program verification via the verification pulse was successful; and
providing a verification pulse via the controller to the set of the word-lines in the one or more of the sub-blocks of each of the planes of the memory device in response to a determination of failure of the program verification.

8. The method of claim 7, further comprising:
determining via the controller which one of the planes fails the program verification in response to providing the verification pulse to the set of the word-lines in the one or more of the sub-blocks of each of the planes of the memory device;
providing another programming pulse via the controller to each of the word-lines in each of the sub-blocks of the respective plane that was identified as failing the program verification; and
providing another verification pulse via the controller to each of the word-lines in each of the sub-blocks of the respective plane that was identified as failing the program verification in response to the other programming pulse.

9. The method of claim 7, further comprising:
determining via the controller if the program verification via the other verification pulse was successful on the respective plane to which the other programming pulse was provided;
determining via the controller if a stop condition is achieved in response to the program verification via the other verification pulse on the respective plane being unsuccessful; and
iteratively providing yet another programming pulse and yet another verification pulse via the controller to the respective plane until the program verification is successful or the stop condition is achieved.

10. The method of claim 1, further comprising:
selecting between an all plane programming mode and a single plane programming mode via the controller; and
selecting one or more planes to provide the proper subset of the planes via the controller;
wherein providing the verification pulse comprises selectively providing the verification pulse to the set of the word-lines in the one or more of the sub-blocks of the selected one or more planes of the memory device.

11. A system for programming data in a memory device, comprising:
a memory device; and
a processing device coupled to the memory device, the processing device to perform a data programming operation, the data programming operation comprising:
providing a programming pulse to each of a plurality of word-lines in each of a plurality of sub-blocks of each of a plurality of planes of the memory device; and
providing a verification pulse selectively to a set of the word-lines in one or more of the sub-blocks of a proper subset of the planes of the memory device.

12. The system of claim 11, wherein providing the verification pulse comprises providing the verification pulse to each of the word-lines in the one or more of the sub-blocks of one of the planes of the memory device.

13. The system of claim 11, further comprising:
determining if program verification via the verification pulse was successful; and
providing a verification pulse to the set of the word-lines in the one or more of the sub-blocks of each of the planes of the memory device in response to a determination of failure of the program verification.

14. The system of claim 13, further comprising:
determining which one of the planes fails the program verification in response to providing the verification pulse to the set of the word-lines in the one or more of the sub-blocks of each of the planes of the memory device;
providing another programming pulse to each of the word-lines in each of the sub-blocks of the respective plane that was identified as failing the program verification; and
providing another verification pulse to each of the word-lines in each of the sub-blocks of the respective plane that was identified as failing the program verification in response to the other programming pulse.

15. The system of claim 14, further comprising:
determining if the program verification via the other verification pulse was successful on the respective plane to which the other programming pulse was provided;
determining if a stop condition is achieved in response to the program verification via the other verification pulse on the respective plane being unsuccessful; and
iteratively providing yet another programming pulse and yet another verification pulse to the respective plane until the program verification is successful or the stop condition is achieved.

16. A non-transitory computer-readable storage medium comprising instructions that, when executed by a processing device, cause the processing device to perform operations comprising:
providing a programming pulse to each of a plurality of word-lines in each of a plurality of sub-blocks of each of a plurality of planes of the memory device; and
providing a verification pulse selectively to a set of the word-lines in one or more of the sub-blocks of a proper subset of the planes of the memory device.

17. The medium of claim 16, wherein providing the verification pulse comprises providing the verification pulse to each of the word-lines in the one or more of the sub-blocks of one of the planes of the memory device.

18. The medium of claim 16, further comprising:
determining if program verification via the verification pulse was successful; and
providing a verification pulse to the set of the word-lines in the one or more of the sub-blocks of each of the planes of the memory device in response to a determination of failure of the program verification.

19. The medium of claim 18, further comprising:
determining which one of the planes fails the program verification in response to providing the verification pulse to the set of the word-lines in the one or more of the sub-blocks of each of the planes of the memory device;
providing another programming pulse to each of the word-lines in each of the sub-blocks of the respective plane that was identified as failing the program verification; and
providing another verification pulse to each of the word-lines in each of the sub-blocks of the respective plane that was identified as failing the program verification in response to the other programming pulse.

20. The medium of claim 19, further comprising:
determining if the program verification via the other verification pulse was successful on the respective plane to which the other programming pulse was provided;
determining if a stop condition is achieved in response to the program verification via the other verification pulse on the respective plane being unsuccessful; and
iteratively providing yet another programming pulse and yet another verification pulse to the respective plane until the program verification is successful or the stop condition is achieved.
